(19) United States
(12) Patent Application Publication
(10) Pub. No.: US 2025/0111527 A1
(43) Pub. Date: Apr. 3, 2025

(54) SYSTEMS, METHODS, AND APPARATUS FOR LOCATING FAULTS OR CONDITIONS OF SYSTEMS

(71) Applicant: The Boeing Company, Arlington, VA (US)

(72) Inventors: David Lee, Arlington, VA (US); Paul Davies, Arlington, VA (US); Charles Goodrow, Arlington, VA (US); Christopher Scott, Arlington, VA (US); Job Munoz, Arlington, VA (US)

(21) Appl. No.: 18/480,329

(22) Filed: Oct. 3, 2023

(51) Int. Cl. G06T 7/33; G01R 31/08; G06T 19/00

(52) U.S. Cl. CPC G06T 7/344; G01R 31/08; G06T 19/003

(57) ABSTRACT

A portable electronic device for assisting a user in locating a condition of a system within a real-world environment is disclosed. The portable electronic device may include a display, an image capture device, and a processor. The processor may be configured to receive, from the image capture device, image data associated with a representation of the real-world environment and to align a virtual model with the real-world environment. The processor may also be configured to receive information associated with the condition of the system and to determine a location in the virtual model corresponding to the condition of the system. Further, the processor may provide a graphical indicator to be displayed over the representation of the real-world environment. The graphical indicator may be displayed at a location on the display that corresponds to a physical location of the condition of the system in the real-world environment.

### FIELD

The present disclosure relates generally to augmented reality systems and, more particularly, to augmented reality systems for identifying locations of faults or conditions of a system within a physical environment, such as a system within an aircraft.

### BACKGROUND

This background description is provided for the purpose of generally presenting the context of the disclosure. Unless otherwise indicated herein, material described in this section is neither expressly nor impliedly admitted to be prior art to the present disclosure or the appended claims.

Complex systems, such as modern aircraft, may have a large amount of electrical wiring. The electrical wiring may be used to distribute power and/or data to various types of devices in a system. The medium or connections through which power and data flow between devices may be referred to as paths. A path may include any component that connects to a device, such as an electrical wire, an optical cable, a network cable, or any other type of path capable of transmitting or routing power and/or data. These systems of connections and devices may be referred to as electrical wiring systems.

Electrical wiring systems may operate with degraded performance due to failures or inconsistencies in one or more connections and/or devices. Such failures or inconsistencies may cause a loss of power or communication in various portions of the electrical wiring system. For example, intermittent connection problems may result from inconsistencies (e.g., faults) in the electrical wiring system. Inconsistencies are commonly reworked in order to resume normal operation of the electrical wiring system. For example, a connector between multiple wires may stop operating normally when one or more wires in the connector become loose or unconnected and the connector and/or wire may need to be reworked or replaced to resume normal operation of the connector.

In some cases, the reworking of the connector and/or wire may require a large amount of time and energy for a technician to locate and expose the connector and/or wire. For example, a technician may remove one or more panel covers of the interior of the aircraft to reach a connector. The technician may then reconnect the wire to the connector so that the wires in each portion of the connector meet as designed. Finally, the technician may replace the panel covers to cover the connector.

A technician will attempt to locate an inconsistency in an electrical wiring system before reworking the inconsistency. One reason the technician locates the inconsistency is to determine what portion or portions of the electrical wiring system must be reworked or replaced to restore normal operation of the electrical wiring system. Due to the complexity of electrical wiring systems in use today, locating inconsistencies can be cumbersome and/or time consuming.

A technician may locate one or more inconsistencies by performing tests to locate one or more areas of the electrical wiring system that are not performing normally. In some cases, tests are inconclusive or only accurate to a certain degree of specificity. For example, testing the electrical wiring system may indicate to a technician that an inconsistency in the electrical wiring system is located between two points in a wire that has numerous connectors. Further, when the electrical wiring system is installed over a large area, such in aircraft, it may difficult for the technician to determine a location of the inconsistency in the electrical wiring system and a location to access the inconsistency.

The technician may make an assumption, based on testing, of the location of the inconsistency and may expend time and energy locating, reaching, reworking and/or replacing the portions of the electrical wiring system. In some cases, the assumption was incorrect and the electrical wiring system remains in a degraded state of operation. In other cases, the technician may spend more resources on locating the inconsistency (e.g., fault) of the electrical wiring system than necessary. As such, the technician may have spent significant time, money, and energy to return the electrical wiring system to normal operation than the technician would have spent if the location of the one or more inconsistencies in the wiring system were located more precisely.

For at least these reasons, it would be advantageous to develop systems and methods that quickly and accurately locate a fault or condition of a system within a physical environment.

### SUMMARY

The present application is directed to embodiments relating to systems, methods, and apparatus for locating faults or conditions of a system within a physical, real-world environment. The embodiments may be used for maintaining, repairing, and/or replacing components of a system, such as an aircraft system. The embodiments can provide a relatively simple and cost-effective solution to identify a fault and/or a condition of a system within the real-world environment.

The embodiments may assist a technician or maintenance personal in quickly and accurately locating failures and/or adverse conditions of a system. For example, the embodiments may reliably identify a location of a fault or condition (e.g., a faulty wire or failed component of an aircraft) in a system. The system may be installed within a physical environment (e.g., workspace), such as a fuselage of an aircraft. Further, the embodiments may identify access points or locations to access the fault or condition of the system within the physical environment.

The embodiments may be configured to efficiently and accurately align a virtual model with a physical environment. The virtual model may be representative of the physical environment (e.g., a workspace). The embodiments may also be configured to use the virtual model to quickly determine a virtual or spatial location of a fault or condition of a system within the virtual model. The virtual location of the fault or condition of the system may be used by the embodiments to determine a location of the fault or condition in the physical environment. For example, the embodiments may transform or convert the virtual location of the fault or condition of the system within the virtual model to a physical location within the physical environment.

The embodiments may be configured to display graphical or visual content to assist a technician in locating the fault or condition within the physical environment so that the technician may resolve and/or fix the fault or condition of the system. The embodiments may display the graphical content to identify the location of the fault or condition in the real-world environment. For example, the embodiments can display a visual indicator at the location of the fault or condition in a live view of a representation of the physical environment. The graphical content may be displayed over (e.g., superimposed on) a representation of the physical environment at a location that corresponds to the physical location of the fault or condition of the system in the real-world environment. As such, the embodiments may enable a technician to visually identify the location of the fault or condition of a system within the physical environment. Further, the embodiments can enable the technician to determine possible access points or a locations to access the fault or condition, reducing the time and labor cost for locating the fault or condition.

By enabling the efficient and reliable identification of faults and conditions in a system, the embodiments may can improve the process for troubleshooting a system by decreasing the time required to identify and repair faults and conditions of a system, such as a faulty wire or component of an aircraft system. The embodiments may also reduce the number of non-faulty components that are replaced, thereby decreasing maintenance costs and improving inventory control relative to conventional troubleshooting processes that often times replace components that are still operational or working properly. Further, the embodiments may also advantageously increase system reliability, safety, maintainability, availability, and affordability resulting in improved performance and operational capabilities of the system. Additionally, in the aircraft industry, the embodiments may reduce the number of flights that are delayed or cancelled for maintenance or repair issues.

In one aspect, a portable electronic device for assisting a user in locating a condition of a system within a real-world environment is disclosed. The portable electronic device may include a display, an image capture device, and a processor. The processor may be configured to receive, from the image capture device, image data associated with a representation of the real-world environment and to align a virtual model with the real-world environment. The virtual model may be a representation of the real-world environment. The processor may also be configured to receive information associated with the condition of the system and to determine a location in the virtual model corresponding to the condition of the system. Further, the processor may be configured to provide a graphical indicator to be displayed over the representation of the real-world environment. The graphical indicator may be displayed at a location on the display that corresponds to a physical location of the condition of the system in the real-world environment.

In another aspect, a method for assisting a user in locating a condition of a system within a real-world environment is disclosed. The method may comprise receiving image data associated with a representation of a real-world environment and aligning a virtual model with the real-world environment. The virtual model may be a representation of the real-world environment. The method may also comprise receiving information associated with the condition of the system and determining a location in the virtual model corresponding the condition of the system. Further, the method may comprise providing a graphical indicator to be displayed over the representation of the real-world environment. The graphical indicator may be displayed at a location on a display that corresponds to a physical location of the condition of the system in the real-world environment.

In still another aspect, a non-transitory computer-readable medium storing instructions is disclosed that, when the instructions are executed by one or more processors, causes the one or more processors to perform operations for assisting a user in locating a condition of a system within a real-world environment. The operations may include receiving image data associated with a representation of a real-world environment and aligning a virtual model with the real-world environment. The virtual model may be a representation of the real-world environment. The operations may also include receiving information associated with the condition of the system and determining a location in the virtual model corresponding the condition of the system. Further, the operations may include providing a virtual indicator to be displayed over the representation of the real-world environment. The virtual indicator may be displayed at a location on a display that corresponds to a physical location of the condition of the system in the real-world environment.

The foregoing summary is illustrative only and is not intended to be in any way limiting. In addition to the illustrative aspects, embodiments, and features described above, further aspects, embodiments, and features will become apparent by reference to the figures and the following detailed description.

### BRIEF DESCRIPTION OF THE DRAWINGS

A more complete understanding of embodiments of the present application may be derived by referring to the detailed description and claims when considered in conjunction with the following figures, wherein like reference numbers refer to similar elements throughout the figures. The figures are provided to facilitate understanding of the disclosure without limiting the breadth, scope, scale, or applicability of the disclosure. The drawings are not necessarily made to scale.

FIG. 1 is an illustration of an exemplary aircraft;

FIG. 2 is a schematic illustration of an augmented reality system used to locate faults or conditions of a system within a physical environment;

FIG. 3 is a front view of a portable electronic device of the augmented reality system of FIG. 2;

FIG. 4 is a rear view of the portable electronic device of FIG. 3;

FIG. 5 is a schematic illustration of the portable electronic device of FIG. 3; and

FIG. 6 is an exemplary flow diagram illustrating a method of identifying a location of a fault or condition of a system within a physical environment.

### DETAILED DESCRIPTION

The figures and the following description illustrate specific exemplary embodiments. It will be appreciated that those skilled in the art will be able to devise various arrangements that, although not explicitly shown herein, embody the principles described herein and are included within the scope of the claims that follow this description. Furthermore, any examples described herein are intended to aid in understanding the principles of the disclosure and are to be construed as being without limitation. As a result, this disclosure is not limited to the specific embodiments or examples described below, but by the claims and their equivalents.

Particular embodiments are described herein with reference to the drawings. In the description, common features are designated by common reference numbers throughout the drawings. In some drawings, multiple instances of a particular type of feature may be used. Although these features are physically and/or logically distinct, the same reference number may be used for each, and the different instances are distinguished by addition of a letter to the reference number.

As used herein, various terminology is used for the purpose of describing particular implementations only and is not intended to be limiting. For example, the singular forms “a,” “an,” and “the” are intended to include the plural forms as well, unless the context clearly indicates otherwise. Further, the terms “comprise,” “comprises,” and “comprising” are used interchangeably with “include,” “includes,” or “including.” Additionally, the term “wherein” is used interchangeably with the term “where.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to a grouping of one or more elements, and the term “plurality” refers to multiple elements.

The present application is directed to embodiments relating to systems, methods, and apparatus for locating faults or conditions of a system within a physical, real-world environment. The embodiments may be used for maintaining, repairing, and/or replacing components of a system, such as an aircraft system. The embodiments can provide a relatively simple, quick, cost-effective, and accurate solution to identify a fault and/or a condition of a system within the real-world environment.

The embodiments may assist a technician or maintenance personal in quickly and accurately locating failures and/or adverse conditions of a system. For example, the embodiments may reliably identify a location of a fault or condition (e.g., a faulty wire or failed component of an aircraft) in a system. The system may be installed within a physical environment (e.g., workspace), such as a fuselage of an aircraft. Further, the embodiments may identify access points or locations to access the fault or condition of the system within the physical environment.

The embodiments may be configured to efficiently and accurately align a virtual model with a physical environment. The virtual model may be representative of the physical environment (e.g., a workspace). The embodiments may also be configured to use the virtual model to quickly determine a virtual or spatial location of a fault or condition of a system within the virtual model. The virtual location of the fault or condition of the system may be used by the embodiments to determine a location of the fault or condition in the physical environment. For example, the embodiments may transform or convert the virtual location of the fault or condition of the system within the virtual model to a physical location within the physical environment.

The embodiments may be configured to display graphical or visual content to assist a technician in locating the fault or condition within the physical environment so that the technician may resolve and/or fix the fault or condition of the system. The embodiments may display the graphical content to identify the location of the fault or condition in the real-world environment. For example, the embodiments can display a visual indicator at the location of the fault or condition in a live view of a representation of the physical environment. The graphical content may be displayed over (e.g., superimposed on) a representation of the physical environment at a location that corresponds to the physical location of the fault or condition of the system in the real-world environment. As such, the embodiments may enable a technician to visually identify the location of the fault or condition of a system within the physical environment. Further, the embodiments can enable the technician to determine possible access points or a locations to access the fault or condition, reducing the time and labor cost for locating the fault or condition.

By enabling the efficient and reliable identification of faults and conditions in a system, the embodiments may can improve the process for troubleshooting a system by decreasing the time required to identify and repair faults and conditions of a system, such as a faulty wire or component of an aircraft system. The embodiments may also reduce the number of non-faulty components that are replaced, thereby decreasing maintenance costs and improving inventory control relative to conventional troubleshooting processes that often times replace components that are still operational or working properly. Further, the embodiments may also advantageously increase system reliability, safety, maintainability, availability, and affordability resulting in improved performance and operational capabilities of the system. Additionally, in the aircraft industry, the embodiments may reduce the number of flights that are delayed or cancelled for maintenance or repair issues.

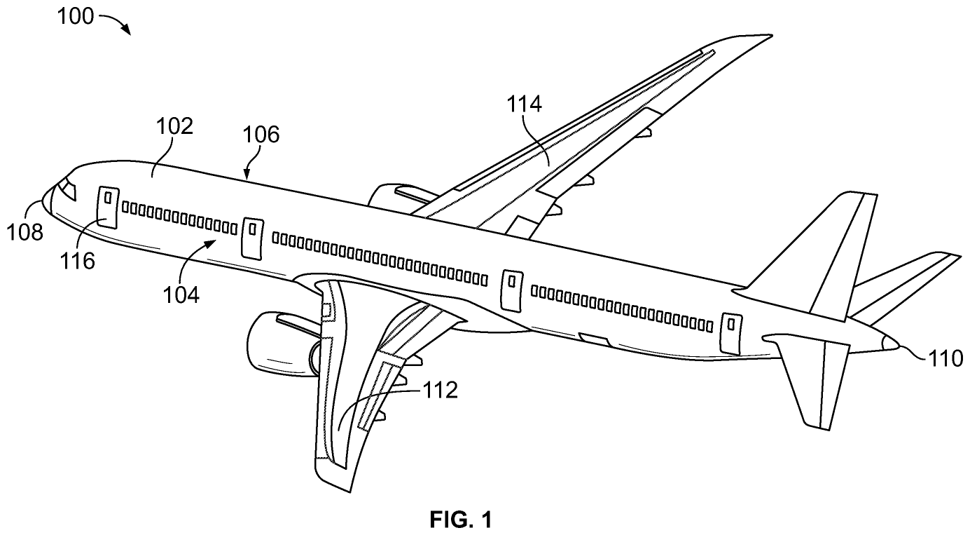

Referring now to the drawings, and more particularly to FIG. 1, an example embodiment of an aircraft 100 is illustrated in which an augmented reality system for identifying a location of a fault or condition of a system can be implemented. The aircraft 100 of FIG. 1 includes a fuselage 102 having a left side 104, a right side 106, a nose end 108 and a tail end 110. A first wing 112 is coupled to the left side 104 of the fuselage 102. A second wing 114 is coupled to the right side 106 of the fuselage 102. In the illustrated example, the aircraft 100 includes a door 116 disposed on the left side 104 of the fuselage 102. Passengers and/or crew may enter (e.g., board) and/or exit (e.g., disembark) the aircraft 100 via the door 116. The aircraft 100 of FIG. 1 is merely an example and, thus, the augmented reality system may be used with other aircrafts or vehicles without departing from the scope of this disclosure.

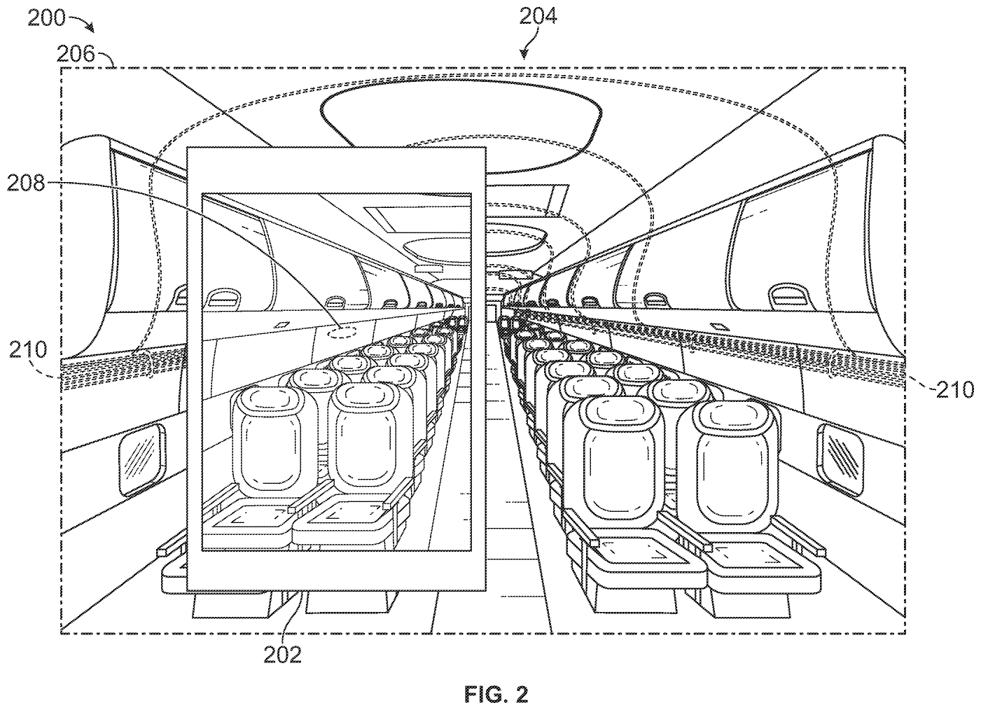

FIG. 2 illustrates an augmented reality system 200, according to an exemplary embodiment. The augmented reality system 200 may include a portable electronic device 202 (e.g., an augmented reality (AR) device) configured to identify locations of faults and/or conditions of a system within a physical, real-world environment. For example, the portable electronic device 202 may enable a technician to visually identify a location of a fault or condition within a physical environment 204. The portable electronic device 202 may be configured to capture physical or sensor data about one or more physical objects within the physical environment 204 and to display the physical data to a technician or user. The physical objects may include structures, systems, electronics, parts, wiring, components, and/or any other suitable physical object in the physical environment.

The physical environment 204 may be any type of environment in the physical world, such as a workspace. In the illustrated example, the physical environment 204 may be within a vehicle 206, such as a fuselage of the aircraft of FIG. 1. In other examples, the physical environment 204 may be, without limitation, a maintenance environment, a manufacturing environment, a production environment, a design environment, an installation environment, and/or any other suitable environment.

The portable electronic device 202 may be configured to display a live view of the physical environment 204 (or a portion thereof) such that a technician or user may view a representation of the physical environment 204 in real time. The portable electronic device 202 may also display graphical or visual content to identify locations of faults or conditions of systems within the physical environment 204. In some examples, the portable electronic device 202 may be used to identify locations of faults or conditions of a system (e.g., an electrical wiring system) installed in the vehicle 206, such as an aircraft.

The portable electronic device 202 may display the graphical content over a representation of the physical environment at a location of the fault or condition in the physical environment 204. The graphical content may be a visual indicator that can provide visual identification of a location of a fault or condition of a system within the physical environment 204. The portable electronic device 202 may display a visual indicator 208 as superimposed or overlaid on a live view of the physical environment 204, thereby providing a composite view of both a representation of the physical environment 204 (or a portion thereof) and the visual indicator 208. As shown in FIG. 2, the portable electronic device 202 may display the visual indicator 208 at a location of a fault or condition of an electrical wiring system 210 within a fuselage of an aircraft. The visual indicator 208 may include an image, a symbol, an icon, an object, one or more letters (e.g., “X”) or colors, a highlighted or emphasized element, or any other suitable visual indicator. In the illustrative example, the visual indicator 208 includes a halo or spherical element. Further, the portable electronic device 202 may provide a ray-trace or arrows to the location of the fault or condition of the system from the user's current location within the physical environment 204.

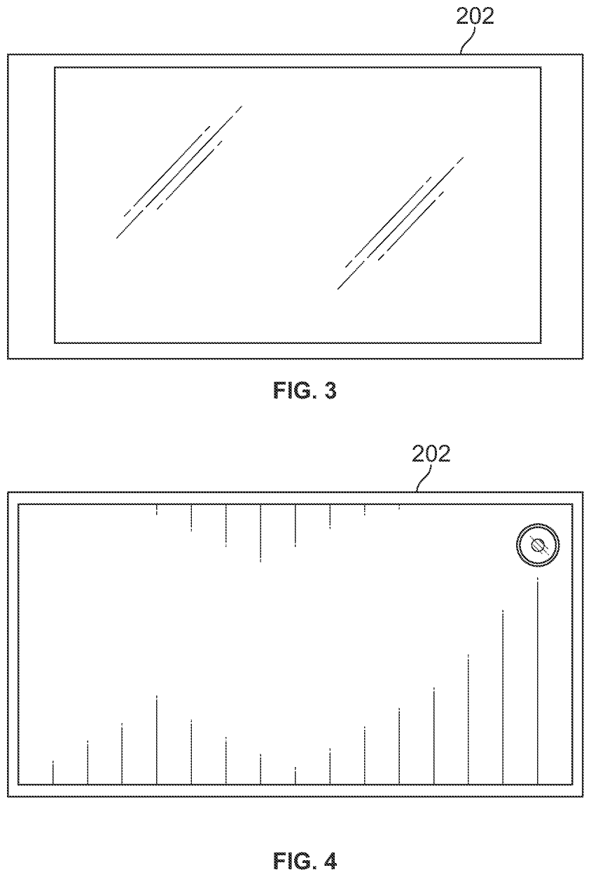

As showing in FIGS. 3 and 4, the portable electronic device 202 of the augmented reality system 200 may be a compact device that may be handled or carried by a user or technician. The portable electronic device 202 may include a smartphone, tablet computer, laptop computer, or any other suitable device. In some examples, the portable electronic device 202 may include a wearable device (e.g., a pair of augmented reality glasses). For example, the wearable device may provide a live view of the physical environment 204 by superimposing a representation of the physical environment 204 on a transparent or translucent display that functions similar to eyeglass lenses, such that a technician is able to view the physical environment 204 through the display.

As shown in FIG. 4, the portable electronic device 202 may include a communication unit 512, a sensor system 514, a storage device 516 (e.g., a memory or a database), a processing unit 518, a user interface 520, and a display device 522. In other examples, the portable electronic device 202 may include additional components, hardware, or functionality. A bus 524 may couple the communication unit 512, the sensor system 514, the storage device 516, the processing unit 518, the user interface 520, and the display device 522 together to enable communication there-between. Although only one bus is depicted, the portable electronic device 202 may include multiple buses or other types of communication pathways between any of its elements or components.

The communication unit 512 of the portable electronic device 202 may be configured to connect to a communications network (not shown). The communication unit 512 may receive data/communications from and send data/communications to other devices within the communication network. The communication unit 512 may enable the portable electronic device 202 to communicate, via a wireless channel or a wired communication link, with test equipment 530 and/or a computing device 532 (e.g., a remote maintenance system). For example, the communication unit 512 may wirelessly receive information from test equipment 530 about a fault or condition of a system. The communication unit 512 may include wireless connections, wired connections, or both and may communicate via a wide area network (WAN), a local area network (LAN), a cellular network, a peer-to-peer communication network, or any other suitable network. The communication unit may also be operative to interface with the communications network using any type of communication protocol such as, for example, Wi-Fi (e.g., 802.xx protocols), a radio frequency (RF) protocol (e.g., 900 MHZ, 1.4 GHz, and 5.6 GHZ), Bluetooth®, a cellular communication protocol (e.g., 2G, 3G, 4G, 5G, etc.), or any other communication protocol.

The sensor system 514 of the portable electronic device 202 may be configured to capture or collect physical or sensor data (e.g., image data and/or proximity data) about one or more physical objects in the physical environment 204. The sensor data may be processed by the processing unit 518 of the portable electronic device 202 to determine the position and orientation of the portable electronic device 202 relative to the physical environment 204. The sensor system 514 may include one or more sensors. For example, the sensor system 514 may include an image capture device or video camera for capturing images of the physical objects in the physical environment 204. The image capture device may be configured to capture image data of the physical environment 204 within its field of view. The captured image data may be displayed on the display device 522 of the portable electronic device 202. In some examples, the image capture device may be a camera including three-dimensional capabilities. As shown in FIG. 4, the imaging capture device may be located at the rear or back of the portable electronic device 202. The sensor system 514 of the portable electronic device 202 may also include range finders (e.g., proximity sensors), infrared (IR) sensors, and/or any other suitable sensor.

The storage device 516 of the portable storage device may store physical or sensor data captured by the sensor system 514 (e.g., image capture device). The storage device 516 may also store information relating to the design of the systems located within the physical environment 204. For example, the storage device 516 may include system information (e.g., schematics, specifications, designs, installation diagrams, etc.) about the architecture and/or structure of systems within the physical environment 204. Further, the storage device 516 may store mapping or positional data that represents a spatial or physical coordinate-based map of the physical objects within the physical environment 204.

The storage device 516 may also store a virtual or digital model. In some examples, the storage device 516 may store a plurality of virtual models. The virtual model may comprise a 3-dimensional virtual model or representation of the physical environment 204. The virtual model of the physical environment 204 may also include the systems within the physical environment 204. The virtual model may represent the systems within the physical environment 204 in an installed or completed state. Further, the systems of the virtual model may include devices and components, and paths between the devices and the components. The paths between the devices and components may be defined by the system information (e.g., designs, specifications, schematics, installation diagrams, etc.). In the illustrated example, the storage device 516 stores a virtual model representing a fuselage of an aircraft and an electrical wiring system that is installed within the fuselage of the aircraft.

The storage device 516 of the portable electronic device 202 may also store program instructions that are executed or carried out by the processing unit 518 of the portable electronic device 202. The storage device 516 may include physical, non-transitory, computer-readable memory that stores data on a temporary or permanent basis for use by the processing unit 518. The memory may include one or more volatile and/or non-volatile memory devices, such as random access memory (RAM), static random access memory (SRAM), dynamic RAM (DRAM), read only memory (ROM), flash memory, or any other suitable medium or memory which may be used to store desired information (e.g., system information, virtual models, mapping information, etc.).

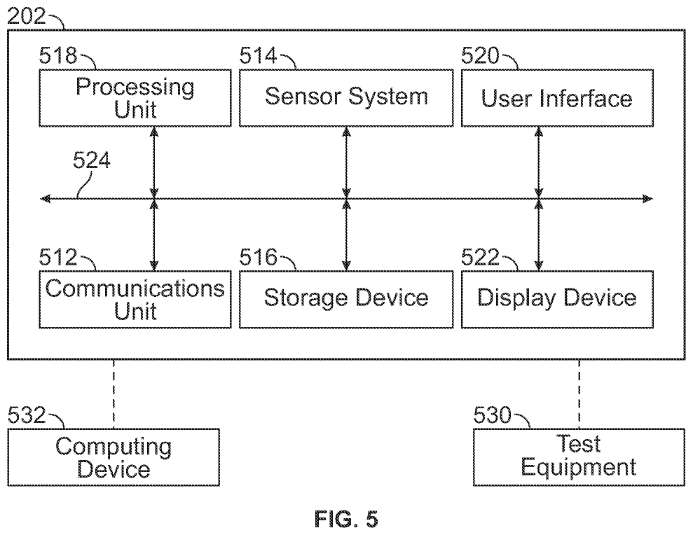

With reference to FIG. 5, the user interface 520 of the portable electronic device 202 may allow a technician or user to interact with the portable electronic device 202. For example, the user interface 520 may be configured to enable a technician or user to input information into the portable electronic device 202 about the physical environment 204 and the systems within the physical environment 204. The user interface 520 also allows a technician to input information relating to a fault or condition of a system within the physical environment 204. The user interface 520 may include an interactive touchscreen. In other examples, the user interface 520 may include a keyboard, a mouse, microphones, or any other suitable input/output device.

The user interface 520 of the portable electronic device 202 may be configured to receive inputs and/or user selections to enable the portable electronic device 202 to select a virtual model representative of the physical environment 204. For example, a technician may input into the user interface 520 information relating to the physical environment 204 (e.g., a model of an aircraft), a system within the physical environment 204 (e.g., an electrical wiring system of an aircraft), a component of a system (e.g., a wire or cable), fault information, and other information related to a system within the physical environment 204.

In the illustrated example, the user interface 520 of the portable electronic device 202 allows a technician to select and/or input information relating to an electrical wiring system of an aircraft. For example, the user interface 520 may enable the technician to input or select a wire or cable of the electrical wiring system. Further, the user interface 520 may allow the technician to input and/or select an end of a wire or cable as a starting point of a path. The technician may also input a distance or linear measurement from either end of the wire or cable to a fault or condition along the installed path of the wire or cable of the electrical wiring system. In other examples, the information relating to the electrical wiring system may be received wirelessly from a separate or remote device, such as the test equipment 530 or the computing device 532. After the information is received, the portable electronic device 202 may display graphical or visual content on the user interface 520 or the display device 522 at a location of the fault or condition of the system within the physical environment 204 as further described below.

The processing unit 518 of the portable electronic device 202 may be in communication with the various components of the portable electronic device 202. The processing unit 518 may be configured to select a virtual model. The virtual model may be a computer-aided design (CAD) model and may use a virtual coordinate system to identify positions of the virtual content of the virtual model. The processing unit 518 may include one or more processors. For example, the processing unit 518 may include one or more central processing units (CPU), one or more graphical processing units (GPU), one or more digital signal processors (DSP), one or more peripheral interface controllers (PIC), or another type of microprocessors.

The processing unit 518 of the portable electronic device 202 may be configured to select or retrieve a virtual model that represents a 3-dimensional virtual model or representation of the physical environment 204 including the systems within the physical environment 204. The virtual model may represent the systems within the physical environment 204 in installed or completed states. Further, the systems of the virtual model may include devices and components, and paths between the devices and the components. The paths between the devices and components may be defined by the information of the systems (e.g., installation diagrams) in an installed state.

In the illustrated embodiment, the processing unit 518 of the portable electronic device 202 may select a virtual model representing a fuselage of an aircraft. The virtual model of the fuselage of the aircraft may include an electrical wiring system installed within the fuselage of the aircraft. In other examples, the processing unit 518 may select, based on the physical environment, a virtual model representing a building, a vehicle, an industrial facility, a power plant, or any other suitable environment.

The processing unit 518 may develop or generate the virtual model based on the design, testing, manufacturing, installation, and/or operational phases of the systems in the physical environment 204. In other examples, the processing unit 518 may retrieve the virtual model from a remote computing device, such as the computing device 532. When the processing unit 518 implements or executes the virtual model, a technician may use the portable electronic device 202 in the physical environment 204 to identify locations of faults or conditions of a system within the physical environment 204.

The processing unit 518 of the portable electronic device 202 may also receive physical or sensor data associated with a physical environment 204 from the sensor system 514. For example, the processing unit 518 may receive image data about the physical objects within the physical environment 204 from the sensor system 514. The processing unit 518 may be configured to determine the location of the physical objects in the physical environment 204 based on image analysis. For example, the processing unit 518 may use image data to determine the distance and orientation of the physical objects relative to the portable electronic device 202.

Further, the processing unit 518 may be configured to map the image data of the physical environment 204 in a physical coordinate system or reference frame. For example, the processing unit 518 may generate mapping or positional data that represents a spatial or physical coordinate-based map of the physical environment 204. The processing unit 518 may map the physical environment 204 to establish a relationship between a position or location of the portable electronic device 202 and the positions of specific physical objects within the physical environment 204 such that, upon mapping the physical environment 204, the physical objects are assigned specific positional coordinates within the physical coordinate system. The physical coordinate system may be based on the position of the portable electronic device 202 within the physical environment 204.

The processing unit 518 may also be configured to track the position and orientation of the portable electronic device 202 within the physical environment 204. The processing unit 518 may process sensor or physical data received from the sensor system 514 to determine the position and orientation of the portable electronic device 202 relative to the physical environment 204. As the portable electronic device 202 moves within the physical environment 204 (e.g., a fuselage of an aircraft), the processing unit 518 may be configured track the physical objects in the physical environment 204 for determining the position and orientation of the portable electronic device 202 within the physical environment 204. For example, the processing unit 518 may track changes in the proximity and angle of the portable electronic device 202 relative to certain features or physical objects in the physical environment 204. In some examples, the physical objects may be particular objects or fiducial markers. Based on the perceived changes in the physical environment 204 surrounding the portable electronic device 202, the processing unit 518 may calculate movement (e.g., translation and/or rotation) of the portable electronic device 202 and determine a current position and orientation of the portable electronic device 202 within the physical environment 204.

The processing unit 518 may be configured to align or spatially-register the virtual model with the physical environment 204. For example, the processing unit 518 may use a transformation or transfer function to align the virtual content of the virtual model using a virtual coordinate system with the physical data of the physical environment 204 using a physical coordinate system. Once the virtual model is aligned with the physical environment 204, the processing unit 518 may be configured to receive fault information of the system. For example, the processing unit 518 may receive input from a technician about a fault or condition of a system within the physical environment 204. In other examples, the fault information may be wirelessly transmitted from a remote or separate device (e.g., the test equipment 530) and received by the processing unit 518.

In the illustrated example, the processing unit 518 receives information about a fault or condition of an electronic wiring system within the fuselage of an aircraft. For example, the processing unit 518 may receive an identification of a path (e.g., an installed wire or cable) in which the fault occurred, an estimate of the location of the fault or condition, a distance or linear measurement from either end of a wire or cable along a path of the installed wire or cable to the fault, a magnitude of the fault, components associated with the fault, and/or any other suitable fault information.

After the information about the fault or condition of the system is received by the processing unit 518 of the portable electronic device 202, the processing unit 518 may be configured to determine a virtual or spatial location of the fault or condition of the system within the virtual content of the virtual model. For example, the processing unit 518 may be configured to implement or execute the virtual model, based on the fault information, to identify a virtual or spatial location of the fault or condition of the system within the virtual model. In the illustrated embodiment, the processing unit 518 may determine a virtual location of the fault or condition of an electrical wiring system within a virtual model of a fuselage of an aircraft.

In determining a virtual location of the fault or condition of the system in the virtual model, the processing unit 518 may traverse a virtual path (e.g., a cable or wire as installed) of the system in which the fault is virtually located to determine the virtual or spatial location of the fault in the virtual content of the virtual model. In the illustrated example, the processing unit 518 may trace or transverse a virtual path along a wire or cable as installed in an electrical wiring system of the virtual model. The virtual path along the wire or cable may start from either end of the wire or cable and extend along the length of the wire or cable until the distance is reached at the virtual location of the fault or condition.

The processing unit 518 may determine a point or location of the fault or condition along the wire or cable starting from either end of the wire or cable. The virtual location may have unique positional coordinates within the virtual coordinate system of the virtual model. The positional coordinates associated with the virtual model may be three-dimensional positional coordinates defined along three mutually-perpendicular axes within the virtual coordinate system. The virtual location of the fault or condition may correspond to a location of the fault or condition of the system within the physical environment 204. In the illustrated example, the virtual location of the fault or condition corresponds to a location of the fault or condition of an electrical wiring system in a fuselage of an aircraft.

After determining the virtual or spatial location of the fault or condition within the virtual content of the virtual model, the processing unit 518 of the portable electronic device 202 may use a transformation or transfer function to translate the virtual positional coordinates of the virtual location of the fault or condition to physical coordinates of a physical location within the physical environment. The positional coordinates of the physical location of the fault or condition of the system within a physical coordinate system may be mapped by the processing unit 518. The physical coordinate system may be three-dimensional and include three mutually-perpendicular axes. In the illustrated embodiment, the processing unit 518 may translate a virtual location of a fault or condition in an electrical wiring system of the virtual model to a physical location in the electrical wiring system in the fuselage of the aircraft.

Further, the processing unit 518 may be configured to generate graphic or visual content to identify the location of the fault or condition of a system within a physical environment 204. For example, the processing unit 518 may provide a visual indicator 208 to overlay on a representation of the physical environment 204 captured by the portable electronic device 202. The visual indicator 208 may be displayed to identify the location of the fault or condition within the physical environment 204. In the illustrated example, the processing unit 518 may provide a halo or spherical element to be displayed over a representation of a fuselage of an aircraft at a location of a fault or condition of the electrical wiring system 210 installed in the fuselage of the aircraft.

Referring still to FIG. 5, the display device 522 of the portable electronic device 202 may be configured to present visual, audio, and/or tactile information to the user or technician. The display device 522 may include a screen or any another suitable type of display. In other examples, the display device 522 may be integrated into a transparent or translucent visor of an optical see-through AR imaging device and viewable by a user or technician wearing the AR imaging device.

The display device 522 of the portable electronic device 202 may be configured to display a live view of the physical environment 204 such that a technician or user is able to view a representation of the physical environment 204 in real time. In the illustrated example, the display device 522 may a display a representation of a fuselage of an aircraft (or a portion thereof). The display device 522 may also display augmented-reality content, such as graphical or visual content, superimposed onto a live view showing the physical environment 204. For example, the display device 522 may display graphical content over or superimposed on a live view of the physical environment 204, thereby providing a composite view of both the physical environment and the virtual content.

The display device 522 of the portable electronic device 202 may also be configured to display graphical or visual content to identify a location of a fault or condition of a system within the physical environment 204. For example, the display device 522 may be configured to display the graphical content at a location of, or aligned with, a fault or condition of the system within the physical environment 204. The graphic content may be a visual indicator that may provide a visual identification of a location of a fault or condition of a system. For example, the visual indicator may enable a technician to visually identify the location of the fault or condition of a system within the physical environment 204. The visual indicator 208 may include an image, a symbol, an icon, an object, one or more letters (e.g., “X”) or colors, a highlighted or emphasized element, or any other suitable indicator.

As shown in FIG. 2, the display device 522 may display a visual indicator 208 at a location of a fault or condition of an electrical wiring system 210 within a fuselage of an aircraft. As shown, the visual indicator 208 is presented as a halo or spherical element. The display device 522 may also provide a ray-trace or arrows to the location of the fault or condition of the system from the user's current location within the physical environment 204. For example, an elongated tubular shape with rounded ends may follow a virtual route and the path of the installed electrical wiring system, depicting a ranged location of the fault or condition.

In some examples, the display device 522 of the portable electronic device may be configured to display a representation of one or more systems located or hidden behind structures/walls and beyond the real world view of the physical environment 204. For example, the display device 522 may depict a graphical image of a schematic diagram of a hidden system installed underlying the panels of a fuselage of an aircraft. The display device 522 may overlay or superimpose the graphical image of the schematic diagram over a representation of the physical environment 204. For example, the display device 522 may display a representation of an electrical wiring system installed and hidden behind panels or walls of the fuselage aircraft over a live view of the fuselage of the aircraft. Further, the display device 522 may align the graphic image of the schematic diagram of the system with the actual location of the system in the physical environment 204. For example, the display device 522 may superimpose a graphical image of the components of an electrical wiring system over a live view of the physical environment at an actual location of the components of the electrical wiring system in the physical environment 204. The display device 522 may also be configured to display fault information on the display device, such as a type of fault or other information.

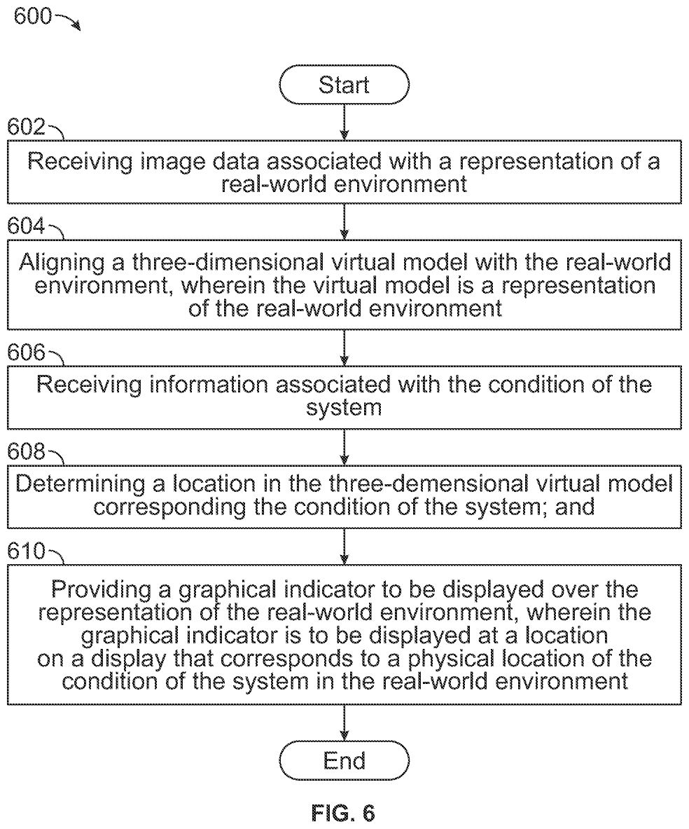

With reference now to FIG. 6, a flow diagram of a method 600 of identifying a location of a fault or condition of a system within a physical environment is illustrated, according to an exemplary embodiment. The method may be performed by an augmented reality system, such as the augment reality system 200 shown in FIG. 2. For example, the method may be performed or implemented entirely, or in part, by an electronic device or AR device, such as the portable electronic device 202 in FIG. 2.

Prior to utilizing a portable electronic device (e.g., the portable electrical device of FIG. 2) of an augmented reality system, a technician may determine an existence or occurrence of a fault or condition of a system within a physical environment. For example, a technician may use test equipment to evaluate and identify faults or conditions of a system within a physical environment. The testing equipment may comprise a fault locator, such as a time domain reflectometer. In other examples, the test equipment may include ohmmeters, ammeters, digital multi-meters, etc. to test the system. In some examples, the test equipment may evaluate systems not visible to the technician within the physical environment and may be hidden behind various structures or walls. For example, when testing an electrical wiring system in a fuselage of an aircraft, the electrical wiring system may be hidden behind walls, floors, and/or panels of the aircraft.

The test equipment may be configured to provide various information about a fault or condition of a system within a physical environment. For example, the test equipment may determine a subsystem or component in which a fault or condition is located, a linear measurement or distance to the fault, an estimate of the location of the fault, a path in which the fault occurred, a magnitude of the fault, components associated with the fault, and/or any other information about a fault or condition of a system. The test equipment may also identify the type of fault, such as, for example, an open circuit, a high impedance fault, a short circuit, a low impedance fault, and/or other types of faults.

After the technician receives the information about the existence or occurrence of a fault or condition of a system within the physical environment, the technician or a user may input the fault information into the portable electronic device. In other examples, the portable electronic device may wirelessly receive fault information from a remote device, such as test equipment (e.g., the test equipment 530 of FIG. 5). The technician may input various information about the physical environment and systems within the physical environment. The information may be input into the portable electronic device via a user interface. In some examples, the technician may input or select a tail number or registration number associated with an aircraft. The tail number may indicate a specific model of an aircraft. The technician may also input information about a system within a physical environment. For example, a technician may input or select an electrical wiring system or other system of an aircraft. In some examples, the technician may not need to enter information about the physical environment or systems when the portable electronic device is dedicated or associated with a specific physical environment and/or system within the physical environment, such as an electrical wiring system within a fuselage of an aircraft.

Once the information about the physical environment and/or system is received or inputted, the portable electronic device may identify and retrieve a virtual model. The virtual model may be a computer-aided design (CAD) model. The virtual model may be stored in a storage device (e.g., a database) of the portable electronic device. The virtual model may be representative of a physical environment (e.g., workspace), such as a vehicle, a building, an industrial facility, a power plant, or any other suitable environment. In the illustrated embodiment, the virtual model is representative of a fuselage of an aircraft.

The virtual model of the physical environment may include systems represented in a completed or installed state. The systems may include systems of vehicles, structures, or any other suitable system. In the illustrated example, the system of the virtual model may represent an electrical wiring system of an aircraft. In other examples, the systems of the virtual model may include hydraulic systems, air trim systems, environmental systems, flight management systems, navigation systems, communications systems, sensor systems, propulsion systems, flight control systems, electrical systems, pneumatic systems, guidance systems, radar systems, air-conditioning systems, blower systems, air intake systems, and/or any other electronic, mechanical, and/or hardware system of an aircraft. Further, the systems of the virtual model may include components and/or features, such as positions of wiring paths throughout a vehicle or structure, the types of electrical connectors along the wiring paths, the distances between the electrical connectors, the types of wires along the wiring paths, other information regarding wiring within the vehicle or structure, and/or other types of components or combinations thereof.

In some examples, the virtual model may be generated and stored at a remote or separate computing device (e.g., the computing device 532 of FIG. 5) from the portable electronic device and the portable electronic device may access and/or retrieve the virtual model from the remote or separate computing device. The remote or separate computing device may be configured to construct or build the virtual model representative of the physical environment. The virtual model may be constructed or generated during the design, testing, manufacturing, installation, and/or operational phase of the physical environment. The construction of the virtual model may be automated in order to increase the efficiency with which the virtual model is constructed and to reduce inconsistency.

At block 602, the method involves receiving image data associated with a representation of a real-world environment. Once the portable electronic device implements or executes the virtual model, a user or technician may use the portable electronic device (e.g., the portable electrical device of FIG. 2) to identify the location of a fault or condition of a system within the physical, real-world environment. The portable electronic device may receive or capture physical or sensor data associated with the physical environment. For example, the portable electronic device may receive image data about physical objects within the physical environment. In the example illustrated in FIG. 2, the portable electronic device may capture image data about a fuselage of an aircraft.

The portable electronic device may be configured to determine the location of the physical objects in the physical environment. For example, the portable electronic device may determine the distance and orientation of the physical objects within the physical environment relative to the portable electronic device based on image data. The portable electronic device may be configured to map the image data of the physical environment in a physical coordinate system or reference frame. For example, the portable electronic device may generate mapping or positional data that represents a spatial or physical coordinate-based map of the physical environment. The portable electronic device may map the physical environment to establish a relationship between a position of the portable electronic device and the positions of specific physical objects within the physical environment such that, upon mapping the physical environment, the physical objects are assigned specific positional coordinates within the physical coordinate system. The physical coordinate system may be based on the position of the portable electronic device within the physical environment.

The portable electronic device may also be configured to track the position and orientation of the portable electronic device within the physical environment. The portable electronic device may process sensor or physical data to determine the position and orientation of the portable electronic device relative to the physical environment. As the portable electronic device moves within the physical environment (e.g., within a fuselage of an aircraft), the portable electronic device may track features and/or physical objects in the physical environment for determining the position and orientation of the portable electronic device within the physical environment. For example, the portable electronic device may track changes in the proximity and angle of the portable electronic device relative to certain features or physical objects in the physical environment. In some examples, the physical objects may be particular objects or fiducial markers. Based on the perceived changes in the physical environment surrounding the portable electronic device, the portable electronic device may calculate movement (e.g., translation and/or rotation) of the portable electronic device and determine a current position and orientation of the portable electronic device within the physical environment.

At block 604, the method involves aligning a three-dimensional virtual model with the real-world environment, wherein the virtual model is a representation of the real-world environment. The portable electronic device may be configured to align or spatially-register a virtual model with the physical environment. For example, the portable electronic device may use a transformation or transfer function to align the virtual content of the virtual model using a virtual coordinate system with the physical data of the physical environment using a physical coordinate system. The portable electronic device may transform or convert the positional coordinates of the virtual content of the electrical wiring system into positional coordinates in a physical coordinate system. The positional coordinates in the physical coordinate system may correspond to a physical location of the electrical wiring system in the physical, real-world environment.

At block 606, the method involves receiving information associated with the condition of the system. Once the virtual model is aligned with the physical environment, the portable electronic device may be configured to receive information about a fault or condition of a system within the physical environment. For example, a technician may enter information about a fault or condition of a system into the portable electronic device to determine a location of a fault or condition of the system in the physical environment. In other examples, the information about the fault or condition can be received by the portable electronic device over a wireless or wired connection from a separate or remote computing device, such as the test equipment 530 and the computing device 532 of FIG. 5. For example, the portable electronic device may receive an estimate of a location of the fault, an identification of a path in which the fault occurred, a linear measurement or distance to the fault from either end of a wire or cable, a type of fault, a magnitude of the fault, components or systems associated with the fault, and/or any other suitable fault information.

In the example illustrated in FIG. 2, the portable electronic device may be configured to receive information about a fault or condition of an electrical wiring system 210 within the fuselage of an aircraft. For example, the portable electronic device may receive a starting point for locating the fault or condition within the electrical wiring system of the virtual model. The starting point may be at a location of either end of a wire or cable of the electrical wiring system of the virtual model. In some examples, the technician may select the starting point using graphical information displayed on the portable electronic device by touching his or her fingertips against a touchscreen to select the starting point. The portable electronic device may also receive a linear measurement or distance from the starting point to the fault of the system. After the information about the fault or condition of the system is received by the portable electronic device, the portable electronic device may be configured to determine a virtual location of the fault or condition of the system in the virtual content of the virtual model.

A block 608, the method involves determining a location in the three-dimensional virtual model corresponding the condition of the system. After the information about the fault or condition of the system is received by the portable electronic device, the portable electronic device may use the fault information to determine a spatial or virtual location of the fault in the virtual model of the physical environment. The portable electronic device may be configured to implement or execute the virtual model, based on the fault information, to determine a virtual or spatial location of the fault or condition of the system in the virtual content of the virtual model. For example, the portable electronic device may trace or traverse a virtual path of the system within the virtual model in which the fault is located to determine a virtual or spatial location of the fault in the virtual model. In some examples, the portable electronic device may use vertex clusters from a tessellated three dimensional (3D) design model to determine a 3D location at a point in the virtual model.

The portable electronic device may trace or transverse a virtual path of a wire or cable of an electrical wiring system of the virtual model. The virtual path of the wire or cable may start from either end of the wire or cable and extend along the length of the wire or cable until the distance is reached at a virtual position or location of the fault or condition. The portable electronic device may determine a virtual point or location of the fault or condition along the wire or cable starting from either end of the wire. The virtual location of the fault or condition may have unique positional coordinates within a virtual coordinate system of the virtual model. The positional coordinates may be three-dimensional positional coordinates defined along three mutually-perpendicular axes within the virtual coordinate system. The virtual location of the electrical wiring system may correspond to a location of the fault or condition of the system within the physical environment.

After determining the virtual location of the fault or condition of the system in the virtual model, the portable electronic device may use a transformation or a transfer function to translate the virtual location of the fault or condition of the system in the virtual model to a physical location within the physical environment. For example, the portable electronic device may translate or covert the positional or virtual coordinates of the virtual location in the virtual model to positional coordinates of a physical location in the physical environment. The positional coordinates of the physical location within the physical coordinate system may be mapped by the portable electronic device. The physical coordinate system may be three-dimensional and include three mutually-perpendicular axes.

At block 610, the method involves providing a virtual indicator to be displayed over the representation of the real-world environment, wherein the virtual indicator is to be displayed at a location on a display that corresponds to a physical location of the condition of the system in the real-world environment. Once the portable electronic device determines the physical location of the fault or condition of the system within the physical environment, the portable electronic device may be configured to display a live view of the physical environment such that a technician or user is able to view a representation of the physical environment in real time. In the example illustrated in FIG. 2, the portable electronic device may a display a representation of a fuselage of an aircraft (or a portion thereof).

The portable electronic device may also be configured to display graphic or visual content to identify the location of the fault or condition of the system within the physical environment. The portable electronic device may be configured to display the graphical or visual content at a location of, or aligned with, the fault or condition of the system within the physical environment to enable a technician to visually identify the location of the fault or condition of the system on a display of the portable electronic device. The graphical content may be a visual indicator that can provide a visual identification of a location of a fault or condition of a system within a physical environment. For example, the visual indicator may include images, symbols, icons, objects, one or more letters (e.g., “X”) or colors, highlighted or emphasized elements, or any other suitable indicator. In the example illustrated in FIG. 2, the portable electronic device 202 may display a visual indicator 208 at a location of the fault or condition of an electrical wiring system 210 within a fuselage of an aircraft. The visual indicator 208 displayed by the portable electronic device 202 may be a halo or spherical element.

Further, the portable electronic device may superimpose or overlay the visual indicator onto a live feed showing the physical environment, thereby providing a composite view of both the physical environment and the virtual content. For example, the portable electronic device may display the captured image data of physical environment on a display overlaid with a visual indicator identifying the location of the fault or condition of the system within the physical environment. In the example illustrated in FIG. 2, the portable electronic device 202 displays a visual indicator 208 (e.g., a halo or spherical element) over a live view of the physical environment at a location of a fault or condition of an electrical wiring system 210 within a fuselage of an aircraft. The portable electronic device may also display a ray-trace or arrows to the location of the fault or condition of the system from the user's current location within the physical environment. Accordingly, the portable electronic device may assist a user or technician to quickly and easily find and identify where the fault is located within the physical environment and to determine which structure and/or panels need to be removed to access the fault.

In some examples, the portable electronic device may be configured to display a representation of the systems located or hidden behind structures or walls and beyond the real world view of the physical environment. For example, the portable electronic device may display a graphical image of a schematic diagram of a hidden system installed underlying the panels of a fuselage of an aircraft. The portable electronic device may overlay or superimpose the graphical image of the schematic diagram of the system in its installed state over a live view of the physical environment. For example, the portable electronic device may display a representation of the electrical wiring system hidden behind panels or walls of the aircraft in an installed state over a live view of the fuselage of the aircraft.

Further, the portable electronic device may align the graphic image of the schematic diagram of a hidden system with the location of the hidden system in the physical environment. For example, the portable electronic device may superimpose graphical images of components of a hidden system over a live view of the physical environment at the locations of the components of the hidden system in the physical environment. The portable electronic device may also be configured to display fault information on the display device, such as a type of fault.

By utilizing the portable electronic device of the present application, a technician can efficiently troubleshoot complex interconnected systems of a vehicle, machine, or structure. Further, the time required to troubleshoot a fault or condition of a system within a physical environment may be substantially diminished. For the airline industry, the augmented reality system disclosed herein can reduce the number of flights that are delayed or cancelled for repairs and maintenance.

Although the augmented reality system has been generally described and illustrated in conjunction with the fault or condition of a system of an aircraft, the augment reality system can be used to locate a fault or condition of any system having a number of interconnected components, such as the complex systems created by the automotive, marine, electronics, power generation and computer industries. As such, the foregoing description of the utilization of the augmented reality system and method in an aircraft was for purposes of illustration and example and not of limitation since the fault identification procedure described above is equally applicable in many different industries.

Further, the description of the different advantageous arrangements has been presented for purposes of illustration and description, and is not intended to be exhaustive or limited to the examples in the form disclosed. Many modifications and variations will be apparent to those of ordinary skill in the art. Further, different advantageous examples describe different advantages as compared to other advantageous examples. The example or examples selected are chosen and described in order to best explain the principles of the examples, the practical application, and to enable others of ordinary skill in the art to understand the disclosure for various examples with various modifications as are suited to the particular use contemplated.

The embodiments described herein can be realized in hardware, software, or a combination of hardware and software. For example, the embodiments can be realized in a centralized fashion in at least one computer system or in a distributed fashion where different elements are spread across interconnected computer systems. Any kind of computer system or other apparatus adapted for carrying out the methods described herein can be employed. Further, the embodiments described herein can be embedded in a computer program product, which includes all the features enabling the implementation of the operations described herein and which, when loaded in a computer system, can carry out these operations.

The flowcharts and block diagrams described herein illustrate the architecture, functionality, and operation of possible implementations of systems, methods, and computer program products according to various illustrative embodiments. In this regard, each block in the flowcharts or block diagrams may represent a module, segment, or portion of code, which comprises one or more executable instructions for implementing the specified logical function or functions. It should also be noted that, in some alternative implementations, the functions noted in a block may occur out of the order noted in the drawings. For example, the functions of two blocks shown in succession may be executed substantially concurrently, or the functions of the blocks may sometimes be executed in the reverse order, depending upon the functionality involved.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

By the term “substantially” and “about” used herein, it is meant that the recited characteristic, parameter, or value need not be achieved exactly, but that deviations or variations, including for example, tolerances, measurement error, measurement accuracy limitations and other factors known to skill in the art, may occur in amounts that do not preclude the effect the characteristic was intended to provide.

Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

While apparatus has been described with reference to certain examples, it will be understood by those skilled in the art that various changes can be made and equivalents can be substituted without departing from the scope of the claims. Therefore, it is intended that the present apparatus not be limited to the particular examples disclosed, but that the disclosed apparatus include all embodiments falling within the scope of the appended claims.

What is claimed is:

1. A portable electronic device for assisting a user in locating a condition of a system within a real-world environment comprising:
a display;
an image capture device; and
a processor configured to:
receive, from the image capture device, image data associated with a representation of the real-world environment;
align a three-dimensional virtual model with the real-world environment, wherein the three-dimensional virtual model is a representation of the real-world environment;
receive information associated with the condition of the system;
determine a location in the three-dimensional virtual model corresponding to the condition of the system; and
provide a graphical indicator to be displayed over the representation of the real-world environment, wherein the graphical indicator is to be displayed at a location on the display that corresponds to a physical location of the condition of the system in the real-world environment.

2. The portable electronic device of claim 1, wherein the processor is further configured to generate the graphical indicator for display over the representation of the real-world environment.

3. The portable electronic device of claim 1, wherein the graphical indicator comprises an icon, a symbol, text, or a combination thereof.

4. The portable electronic device of claim 1, wherein the condition comprises a wiring fault or error of the system, and wherein the system comprising an electrical wiring system in an installed state.

5. The portable electronic device of claim 4, wherein at least a portion of the electrical wiring system is hidden from a view of the user in the real-world environment.

6. The portable electronic device of claim 4, wherein the processor is further configured to receive information associated with the electrical wiring system.

7. The portable electronic device of claim 6, wherein the information includes a measurement of a distance from a starting point in the electrical wiring system to the condition.

8. The portable electronic device of claim 7, wherein the starting point is at one end of at least one electrical wire of the electrical wiring system.

9. The portable electronic device of claim 7, wherein the distance is determining by a fault locator, and wherein the fault locator comprises a time domain reflectometer.

10. The portable electronic device of claim 7, wherein the processor is further configured to determine a virtual path along a length of at least one electrical wire of the electrical wiring system, and wherein the virtual path starts from the starting point and extends along the length of the at least one electrical wire until the distance is reached.

11. The portable electronic device of claim 10, wherein the distance is reached at a virtual location of the electrical wiring system, wherein the virtual location of the electrical wiring system corresponds to a location of the condition, and wherein the processor is further configured to determine, based on the virtual location, a physical location of the electrical wiring system in the real-world environment that corresponds to the virtual location of the electrical wiring system.

12. The portable electronic device of claim 11, wherein the processor is further configured to:
determine coordinates of the virtual location of the electrical wiring system in a first coordinate system; and
convert the coordinates of the virtual location of the electrical wiring system into coordinates in a second coordinate system, wherein the coordinates in the second coordinate system correspond to a physical location of the condition of the electrical wiring system in the real-world environment.

13. The portable electronic device of claim 12, wherein the processor is further configured to identify a transform for translating the virtual location of the electrical wiring system in the first coordinate system to coordinates corresponding to the physical location of the condition in the real-world environment in the second coordinate system.

14. The portable electronic device of claim 1, wherein determining of the alignment of the system in the real-world environment with the three-dimensional virtual model of the system further includes determining that at least one virtual object or fiducial of the three-dimensional virtual model is aligned with a corresponding object or fiducial in the real-world environment, and wherein the processor is further configured to provide a notification when the system in the real-world environment is aligned with the three-dimensional virtual model of the system.

15. The portable electronic device of claim 1, wherein the processor is further configured to:
identify the system based on user input; and
receive information including the three-dimensional virtual model of the system from a computing device.

16. The portable electronic device of claim 1, wherein the processor is further configured to:
provide a representation of one or more components of the system for display on the display, wherein the one or more components are hidden from a view of the user; and
provide additional information associated with the one or more components for display on the display.

17. A method for assisting a user in locating a condition of a system within a real-world environment comprising:
receiving, by one or more processors, image data associated with a representation of a real-world environment;
aligning, by the one or more processors, a three-dimensional virtual model with the real-world environment, wherein the three-dimensional virtual model is a representation of the real-world environment;
receive, by the one or more processors, information associated with the condition of the system;
determining, by the one or more processors, a location in the three-dimensional virtual model corresponding the condition of the system; and
providing, by the one or more processors, a graphical indicator to be displayed over the representation of the real-world environment, wherein the graphical indicator is to be displayed at a location on a display that corresponds to a physical location of the condition of the system in the real-world environment.

18. The method of claim 17, wherein the graphical indicator comprises an icon, a symbol, text, or a combination thereof, wherein the condition comprises a fault or error of the system, and wherein the system comprising an electrical wiring system in an installed state.

19. The method of claim 18, further comprising:
determining a virtual path along a length of at least one electrical wire of the electrical wiring system, and wherein the virtual path starts from a starting point and extends along the length of the at least one electrical wire to a virtual location of the electrical wiring system, and wherein the virtual location of the electrical wiring system corresponds to a location of the condition; and
determining, based on the virtual location, a physical location of the electrical wiring system in the real-world environment that corresponds to the virtual location of the electrical wiring system.

20. A non-transitory computer-readable medium storing instructions that, when the instructions are executed by one or more processors, cause the one or more processors to perform operations for assisting a user in locating a condition of a system within a real-world environment comprising:
receiving image data associated with a representation of the real-world environment;
aligning a three-dimensional virtual model with the real-world environment, wherein the three-dimensional virtual model is a representation of the real-world environment;
receiving information associated with the condition of the system;
determining a location in the three-dimensional virtual model corresponding the condition of the system; and
providing a virtual indicator to be displayed over the representation of the real-world environment, wherein the virtual indicator is to be displayed at a location on a display that corresponds to a physical location of the condition of the system in the real-world environment.
